(19) United States
(12) Patent Application Publication
(10) Pub. No.: US 2026/0239887 A1
(43) Pub. Date: Aug. 13, 2026

(54) MAGNETIC TUNNEL JUNCTIONS HAVING FREE LAYER WITH LOW MAGNETIZATION AND PERPENDICULAR SHAPE ANISOTROPY

(71) Applicants: International Business Machines Corporation, Armonk, NY (US); Samsung Electronics Co., Ltd., Gyeonggi-Do (KR)

(72) Inventors: See-Hun Yang, Morgan Hill, CA (US); Panagiotis Charilaos Filippou, Fremont, CA (US); Mahesh Samant, San Jose, CA (US); Dmytro Apalkov, San Jose, CA (US); Fnu Ikhtiar, San Jose, CA (US); Jaewoo Jeong, Los Altos, CA (US)

(21) Appl. No.: 19/048,838

(22) Filed: Feb. 7, 2025

(51) Int. Cl. H10N 50/10; H10B 61/00; H10N 50/85

(52) U.S. Cl. CPC H10N 50/10; H10B 61/22; H10N 50/85

(57) ABSTRACT

A magnetoresistive random-access memory cell includes a fixed magnetic layer and a free magnetic layer formed from an ordered magnetic alloy. The free magnetic layer has a diameter less than 20 nm, and the free magnetic layer exhibits magneto-crystalline anisotropy with magnetization substantially perpendicular to the free magnetic layer. A tunnel barrier is located between the fixed and free magnetic layers. A magnetoresistive random-access memory array of such cells, and corresponding design structures, are also provided.

### BACKGROUND

The present invention relates generally to the electrical, electronic and computer arts and, more particularly, to magnetoresistive random-access memory (MRAM).

Current MRAM devices use a magnetic tunnel junction (MTJ) as a storage element. A simple MTJ is a tri-layer structure containing two magnetic layers separated by a tunnel barrier layer. Thus, current MRAMs are three-layer devices employing a magnetic tunnel junction (MTJ). They typically include a reference layer magnet, a tunnel barrier, and a storage or free magnetic layer. Current is passed through the device and the resistance is measured. The resistance changes based on the magnetic orientation of the two magnetic layers, and the relative change in resistance is referred to as the tunnel magnetoresistance (TMR). High TMR is desirable since higher TMR provides a higher ON/OFF ratio. Low switching current is also desirable. The switching current is proportional to the product (Mₛ·V·Hₖ) where Mₛ is saturation magnetization, Vis volume, and Hₖ is anisotropy field.

Perpendicular magnetic anisotropy (PMA) refers to a situation where the magnetic layers have magnetization perpendicular to the film surface. MTJs with magnetic layers having PMA need smaller switching current than for in-plane magnetized layers.

Current devices employ alloys of cobalt, iron, and boron (CoFeB) for the magnetic layers. Indeed, CoFeB is universally used both as storage layer (free layer) and reference layer in current MRAM applications; however, the two layers are configured differently. CoFeB is amorphous as deposited. Annealing at modest temperatures (e.g., around 300° C.) leads to crystallization of the CoFeB layer with B atoms leaving the CoFe matrix, which leads to crystallization of Co and Fe. The crystallized CoFe layer displays PMA, but only in a narrow range of thicknesses; the origin of this PMA is interfacial anisotropy. This interfacial anisotropy (at the interface between the CoFe and the MgO tunnel barrier) limits the minimum size of the MTJ device with CoFeB free layer having necessary thermal stability. Currently, an MTJ device with a minimum size of ~30 nm diameter has demonstrated a thermal stability parameter, E_{B}, of ~40 kT (implying that the device will survive 10 years if left alone). Bulk PMA (due to crystallinity, not the interface) can be achieved using Mn₃Ge.

### BRIEF SUMMARY

Principles of the invention provide techniques for magnetic tunnel junctions having a free layer with low magnetization and perpendicular shape anisotropy. In one aspect, an exemplary magnetoresistive random-access memory cell includes a fixed magnetic layer; a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and a tunnel barrier between the fixed and free magnetic layers.

In still another aspect, a magnetoresistive random-access memory array of such magnetoresistive random-access memory cells includes a plurality of bit lines and a plurality of complementary bit lines forming a plurality of bit line-complementary bit line pairs; a plurality of word lines intersecting the plurality of bit line pairs at a plurality of cell locations; and a plurality of magnetoresistive random-access memory cells located at each of the plurality of cell locations. Each of the magnetoresistive random-access memory cells is electrically connected to a corresponding bit line and selectively interconnected to a corresponding one of the complementary bit lines under control of a corresponding one of the word lines. Each of the plurality of magnetoresistive random-access memory cells includes: a fixed magnetic layer; a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and a tunnel barrier between the fixed and free magnetic layers.

In yet a further aspect, a hardware description language (HDL) design structure is encoded on a machine-readable data storage medium. The HDL design structure includes elements that when processed in a computer-aided design system generate a machine-executable representation of a magnetoresistive random-access memory cell and/or array, as described.

Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIGS. 1-8 depict a micromagnetic simulation with a quasi-uniform rotation model, in accordance with aspects of the invention;

FIG. 9 shows a plot of energy along switching trajectory versus number of “nudged elastic bands” for the simulation, in accordance with aspects of the invention;

FIGS. 10 and 11 present a comparison of Δ from a macro-spin (MS) based formula and Δ from a micromagnetic simulation, in accordance with aspects of the invention;

FIGS. 12 and 13 depict effects of diameter and aspect ratio on Δ for the PSA (Perpendicular Shape Anisotropy) case, in accordance with aspects of the invention;

FIGS. 14 and 15 illustrate the effect of different materials with different values of saturation magnetization Mₛ, in accordance with aspects of the invention;

FIG. 16 illustrates techniques to restore Δ for an Mn₃Ge-like free layer, in accordance with aspects of the invention;

FIG. 17 compares Mn₃Ge to CoFeB layer, in accordance with aspects of the invention;

FIGS. 18, 19A, and 19B depict embodiments of MTJs with a low Mₛ free layer, in accordance with aspects of the invention;

FIG. 20 shows a Heusler compound employed in aspects of the invention;

FIG. 21 shows growth of a Heusler compound on a templating layer according to aspects of the invention;

FIG. 22 shows an array of MRAM cells, according to an aspect of the invention;

FIG. 23 depicts a computing environment according to an embodiment of the present invention (e.g., for implementing a design process such as that of FIG. 24); and

FIG. 24 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

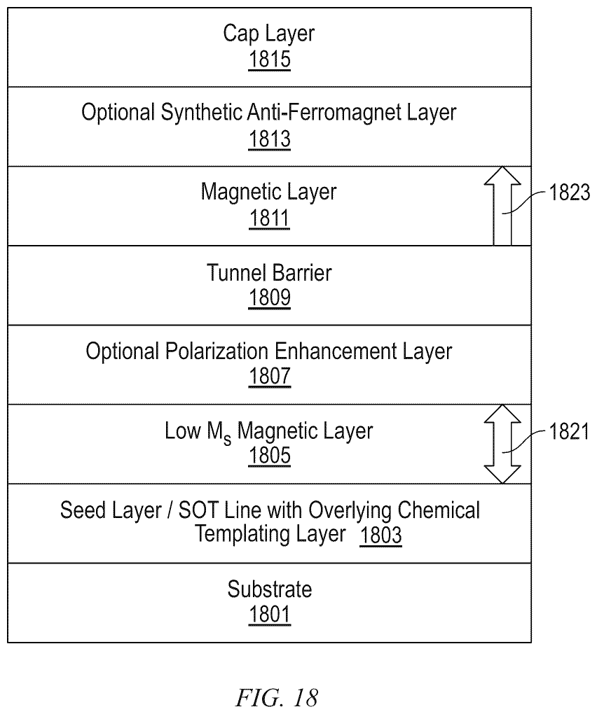

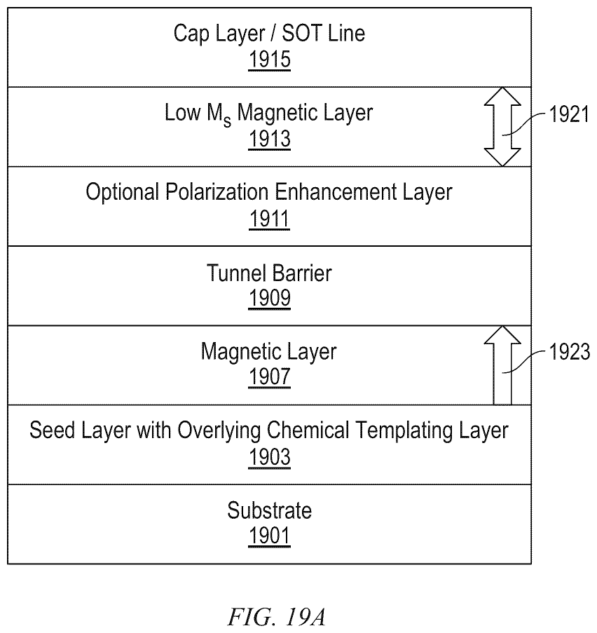

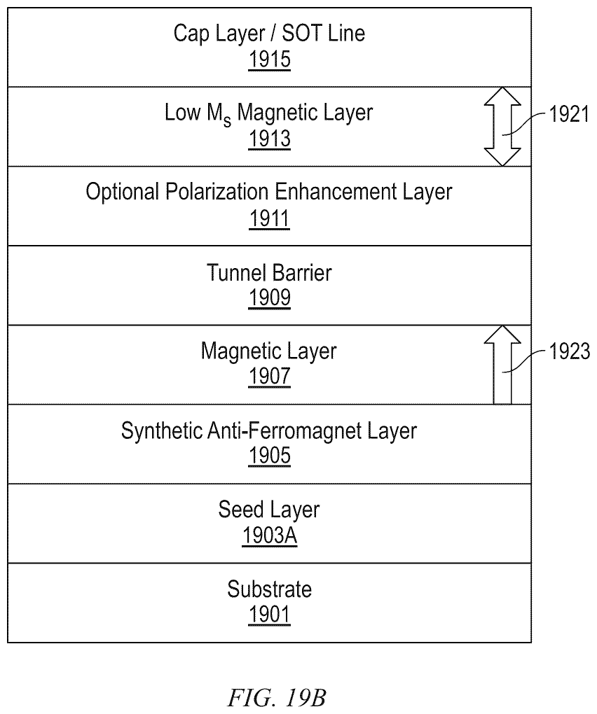

Given the discussion herein (reference characters refer to the drawings discussed below), it will be appreciated that in one aspect, referring, for example, to FIGS. 18, 19A, and 19B, an exemplary magnetoresistive random-access memory cell includes a fixed magnetic layer 1811, 1907 and a free magnetic layer 1805, 1913 formed from an ordered magnetic alloy. The free magnetic layer has a diameter less than 20 nm, and the free magnetic layer exhibits magneto-crystalline anisotropy with magnetization substantially perpendicular to the free magnetic layer. A tunnel barrier 1809, 1909 is located between the fixed and free magnetic layers. As used herein, an “ordered” magnetic alloy refers to a chemical compound having a well-defined crystal structure with lattice parameters. Technical benefits include, for example, a larger margin for free layers with bulk magneto-crystalline anisotropy; and applicability to both top and bottom free layers.

Referring, for example, specifically to FIG. 18, in some cases, the magnetoresistive random-access memory cell further includes a substrate 1801; a cap layer 1815; a seed layer overlying the substrate; and a templating layer overlying the seed layer, the templating layer including a binary alloy having a CsCl structure. Refer generally to element 1803. The free magnetic layer overlies the templating layer, the tunnel barrier is outward of the free magnetic layer, the fixed magnetic layer is outward of the tunnel barrier, and the cap layer is outward of the fixed magnetic layer. Technical benefits include those discussed above, in the specific case of a top free layer.

In some such cases, the ordered magnetic alloy comprises a Heusler compound. The Heusler compound can, for example, be selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In some specific instances, the Heusler compound is Mn₃Ge. Technical benefits include achievement of high switching speed due to a combination of low Mₛ, PSA and magneto-crystalline anisotropy.

In some such cases, the binary alloy with CsCl structure is represented by A₁₋ₓEₓ, where A is a transition metal element and E is a main group element including at least one of aluminum or gallium, and x is in the range from 0.42 to 0.55. Technical benefits include facilitating growth of the free magnetic layer.

In some such cases, the free magnetic layer has a thickness/diameter ratio of less than 2.5. Technical benefits include attaining a high thermal stability parameter.

In some such cases, the ordered magnetic alloy comprises a C38 structure (also known as a Cu₂Sb structure) compound. Technical benefits include those discussed above, with an alternative magnetic alloy.

Referring, for example, specifically to FIGS. 19A and 19B, in some cases, the magnetoresistive random-access memory cell further includes a substrate 1901; a cap layer 1915; and a seed layer 1903, 1903A overlying the substrate. The fixed magnetic layer is outward of the seed layer, the tunnel barrier is outward of the fixed magnetic layer, the free magnetic layer is outward of the tunnel barrier, and the cap layer is outward of the free magnetic layer. Technical benefits include those discussed above, in the specific case of a bottom free layer.

Referring, for example, more specifically to FIG. 19A, in some such cases, the seed layer includes an overlying templating layer (refer generally to element 1903); and the fixed magnetic layer comprises a Heusler layer. The Heusler layer can have, for example, a thickness at least 33 percent greater than that of the free magnetic layer (optionally, at least 40 percent or at least 50 percent greater). Technical benefits include those discussed above, realized with a number of known Heusler materials.

In some such cases, the ordered magnetic alloy comprises a Heusler compound. The Heusler compound can, for example, be selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In some specific instances, the Heusler compound is Mn₃Ge. Technical benefits include achievement of high switching speed due to a combination of low Mₛ, PSA and magneto-crystalline anisotropy.

In some such cases, the free magnetic layer has a thickness/diameter ratio of less than 2.5. Technical benefits include attaining a high thermal stability parameter.

In some such cases, the ordered magnetic alloy comprises a C38 compound. Technical benefits include those discussed above, with an alternative magnetic alloy.

Referring, for example, more specifically to FIG. 19B, in some such cases, the fixed magnetic layer comprises CoFeB. Technical benefits include those discussed above, achieved with a known and readily available material.

In some such cases, the ordered magnetic alloy comprises a Heusler compound. The Heusler compound can, for example, be selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi. In some specific instances, the Heusler compound is Mn₃Ge. Technical benefits include achievement of high switching speed due to a combination of low Mₛ, PSA and magneto-crystalline anisotropy.

In some such cases, the free magnetic layer has a thickness/diameter ratio of less than 2.5. Technical benefits include attaining a high thermal stability parameter.

In some such cases, the ordered magnetic alloy comprises a C38 compound. Technical benefits include those discussed above, with an alternative magnetic alloy.

In another aspect, referring to FIG. 22, a magnetoresistive random-access memory array includes a plurality of bit lines and a plurality of complementary bit lines forming a plurality of bit line-complementary bit line pairs; a plurality of word lines intersecting the plurality of bit line pairs at a plurality of cell locations; and a plurality of magnetoresistive random-access memory cells located at each of the plurality of cell locations. Each of the magnetoresistive random-access memory cells is electrically connected to a corresponding bit line and selectively interconnected to a corresponding one of the complementary bit lines under control of a corresponding one of the word lines, and each of the plurality of magnetoresistive random-access memory cells includes: a fixed magnetic layer and a free magnetic layer formed from an ordered magnetic alloy. The free magnetic layer has a diameter less than 20 nm, and the free magnetic layer exhibits magneto-crystalline anisotropy with magnetization substantially perpendicular to the free magnetic layer. A tunnel barrier is located between the fixed and free magnetic layers. The array can include any of the embodiments of cells described herein. Technical benefits include those discussed above, with a high-density array in which cell-to-cell interaction is reduced.

In further aspects, a hardware description language (HDL) design structure is encoded on a machine-readable data storage medium, The HDL design structure includes elements that when processed in a computer-aided design system generate a machine-executable representation of a magnetoresistive random-access memory cell or array, as described herein. Technical benefits include those discussed above, realized in a computer-aided manner.

Techniques as disclosed herein can provide substantial beneficial technical effects. Some embodiments may not have these potential advantages and these potential advantages are not necessarily required of all embodiments. By way of example only and without limitation, there are a number of advantages of MTJs with a low Mₛ free layer using PSA and magneto-crystalline anisotropy, according to one or more embodiments. These include a larger margin for free layers with bulk magneto-crystalline anisotropy, and moreover, even materials with smaller bulk magneto-crystalline anisotropy can be incorporated using appropriate aspect ratio. An additional advantage is the ability to attain high E_{B} (>80 k_{B}T) at small device diameter (<15 nm). One or more embodiments advantageously reduce or eliminate the need for bulk PMA, such that a wider spectrum of low Mₛ materials can be considered. Additional advantages include temperature dependence being better than interfacial PMA, and the fact that a thicker free layer implies higher TMR and/or smaller damping (damping~1/t, where t=free layer thickness), which in turn implies faster switching. Furthermore, one or more embodiments enable smaller device size, implying the advantage of achieving higher density.

Still further advantages include that the free layer volume decreases with ~1/D² faster compared to 1/t while the anisotropy increases (D=MTJ diameter), implying decrease of V_{C} and increase of efficiency while keeping high E_{B}. Furthermore in this regard, every material has its own saturation magnetization, Mₛ, in emu/cc. If a certain amount of material is present, the Mₛ can be multiplied by the volume. Consider shape anisotropy; that is, the shape of the pillar/device is changed. As the diameter is reduced, the volume decreases as 1/D², which is a faster reduction in volume than if the thickness were to be changed (where volume decreases as 1/t). This changes the shape anisotropy, which is what causes a material that normally has in-plane magnetization (e.g., conventional ferromagnet) to “go perpendicular” because of the columnar shape. Magnetization does not “like” to have south and north poles very close to each other so a relatively tall thin column leads to higher anisotropy energy and thus perpendicularity. This in turn decreases switching voltage, V_{c}, and increases efficiency while keeping a high E_{B}. E_{B} increases with increasing shape anisotropy.

Even further advantages include applicability to both top and bottom free layers (i.e., above and below the tunnel barrier); and that (based on simulations) E_{B} can be maintained down to <6 nm diameter with moderate aspect ratio (see discussions of aspect ratio elsewhere herein), provided that Kᵤ is of the order of 1.0×10⁷ erg/cc. Additional advantages include the fact that cell-to-cell interaction can be minimized (e.g., for a low Mₛ material such as a Heusler alloy such that the total magnetization is smaller; the total moment is smaller for two adjacent pillars/devices and thus the interaction is lower); that the WER (write error rate) slope for fast pulses would be reduced; and that back-hopping (an undesirable effect where bits flip back to their initial state) is expected (based on an understanding of the back-hopping from both experiments and simulations) to improve (smaller Mₛt of the free layer implies smaller H_{demag} (demagnetization field) on the reference layer).

In one or more embodiments, high switching speed can be achieved due to a combination of low Mₛ, PSA and magneto-crystalline anisotropy, based on simulations and experimental data. In a non-limiting example, candidate materials having low Mₛ and magneto-crystalline anisotropy can be Heusler alloys such as Mn₃Ge and others listed herein (e.g., Mn₃Sn, Mn₃Sb, Mn₂CoSn, Mn₂FeSb, Mn₃CoAl, Mn₂CoGe, Mn₂CoSi, Mn₂CuSi, Co₂CrAl, Co₂CrSi, Co₂MnSb, and Co₂MnSi).

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

As noted above, currently, MTJ devices with a minimum size of ~30 nm diameter have a demonstrated E_{B} of ~40 kT. Scaling the MTJ device sizes to lower diameter requires either a free layer with a bulk PMA, or use of additional techniques to support PMA, such as shape anisotropy. If the shape of the device is chosen correctly, it is still possible to obtain PMA from the material.

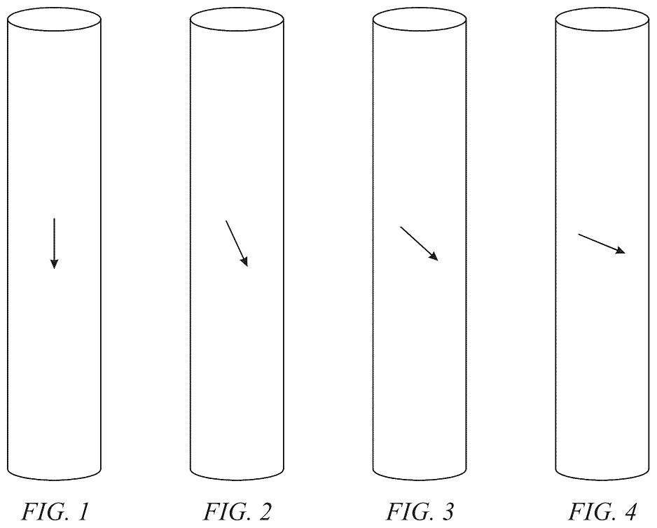

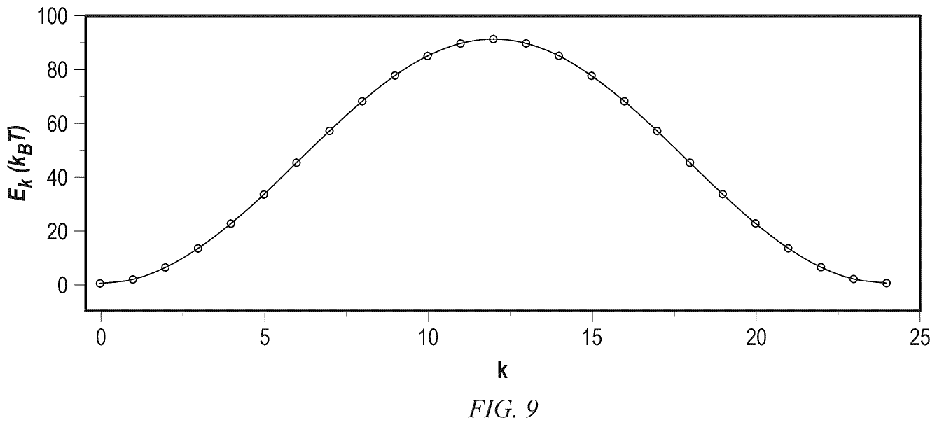

Similar material stacks are used for many current MRAM devices (substrate, bottom electrode, reference layer including CoFeB, tunnel barrier, recording layer including CoFeB, top electrode), with a data retention of 10 years at an MTJ diameter of 20 nm demonstrated for a value of Δ (thermal stability factor of the free layer) of 50 (a dimensionless quantity equal to E_{B}/k_{B}T). The 10 year data retention limitation is due to the CoFeB layer, whose moment is perpendicular due to interfacial anisotropy. The thermal stability of an MTJ device is determined by Energy barrier, E_{B}, (change in energy, Ek, in FIG. 9) separating the two stable orientations of magnetization of the free layer (parallel and anti-parallel). The thermal stability factor, Δ, equals Kᵤ·Volume/k_{B}T, where Kᵤ is magnetic anisotropy energy, k_{B} is Boltzmann's constant and T is the absolute temperature in Kelvin. As junction diameter is reduced, the thermal stability factor Δ continues decreasing; it is undesirable for it to be below approximately 40 or 50. One or more embodiments provide new magnetic materials to facilitate scaling of MRAM devices to sizes below 20 nm. In FIG. 9, there are two equilibrium states, one pointing down (FIG. 1) and the other pointing up (FIG. 8). E_{B} is the energy barrier between these two states.

Thermally stable tunnel junctions have been produced using shape anisotropy, using FeB rather than CoFeB, and with FeB layers thicker than the CoFeB layers used in the interfacial anisotropy case. For an MTJ that it is desired to switch by flowing current, perpendicular magnetization is desirable. It has been found that perpendicular shape anisotropy (PSA) can be promising for small critical dimensions (CDs) (~10 nm diameter or less). Current-induced switching of a free layer with high magnetization (FeB) has been demonstrated with high Jc (critical current density), and high retention, i.e. large thermal stability factor, Δ. However, it has been further found that use of PSA only does not facilitate high switching speed; the demonstrated spin-transfer torque (STT) switching speed was only 10 ms. One or more embodiments of the invention can advantageously achieve high speed switching with a smaller diameter geometry when using Heusler compound, Mn₃Ge or the like.

For the coherent switching case of MTJs having a free layer with PSA:

$${V}_{C} = {V}_{CO} [ 1 + \frac{1}{2} \frac{{τ}_{D}}{{τ}_{P}} log ( \frac{4 Δ}{log 2} ) ] \qquad ( 1 )$$

$${V}_{CO} = \frac{2 αe Δ {k}_{B} TR}{{ℏg}_{STT}} \qquad ( 2 )$$

$${τ}_{D} = \frac{1 + {α}^{2}}{{αγμ}_{0} {H}_{K}^{eff}} . \qquad ( 3 )$$

In the above, V_{C} is switching voltage, Δ is the thermal stability factor, τ_{P} is pulse length, α is Gilbert damping constant, e is the elementary charge, k_{B} is the Boltzmann constant, T is absolute temperature, ℏ is reduced Planck constant, g_{STT} is STT efficiency, R is resistance, y is gyromagnetic ratio, ulo is magnetic permeability,

$${H}_{K}^{eff}$$

is magneto-crystalline anisotropy field, and τ_{D} is a characteristic time scale for switching.

To achieve high switching speed, or shorter τ_{P} with a given V_{C}, a shorter τ_{D} is needed as shown above in Equation (1). To obtain the shorter τ_{D}, a higher

$${H}_{K}^{eff}$$

magnetocrystalline anisotropy field is needed, see Equation (3). A free layer with low Mₛ and some magneto-crystalline anisotropy which includes an ordered Heusler compound (e.g. Mn₃Ge) and PSA, can achieve both high thermal stability and high speed.

The voltage required for switching can be obtained from the literature and has certain dependencies. The parameter τ_{D} is pertinent in one or more embodiments; as noted, it is a characteristic time for switching. It is desirable to have high

$${H}_{K}^{eff}$$

to reduce τ_{D}. CoFeB typically has an

$${H}_{K}^{eff}$$

of a few kOe, while the

$${H}_{K}^{eff}$$

of Mn₃Ge is about ten times larger so that higher switching speed can be obtained. The lower magnetization, Mₛ, of Mn₃Ge is also helpful when trying to reduce switching speed.

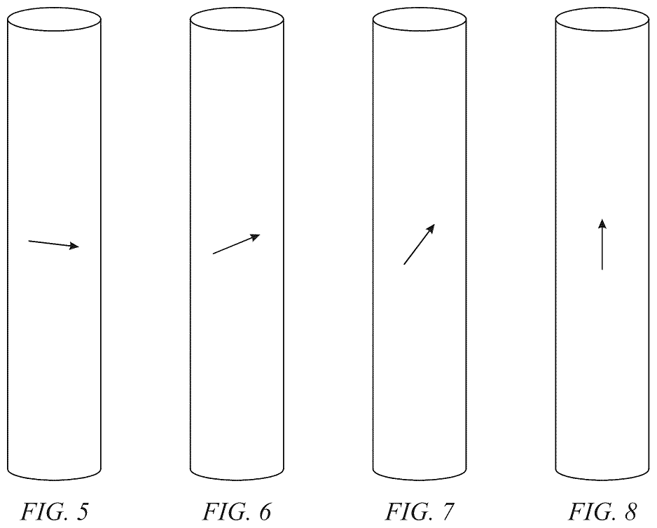

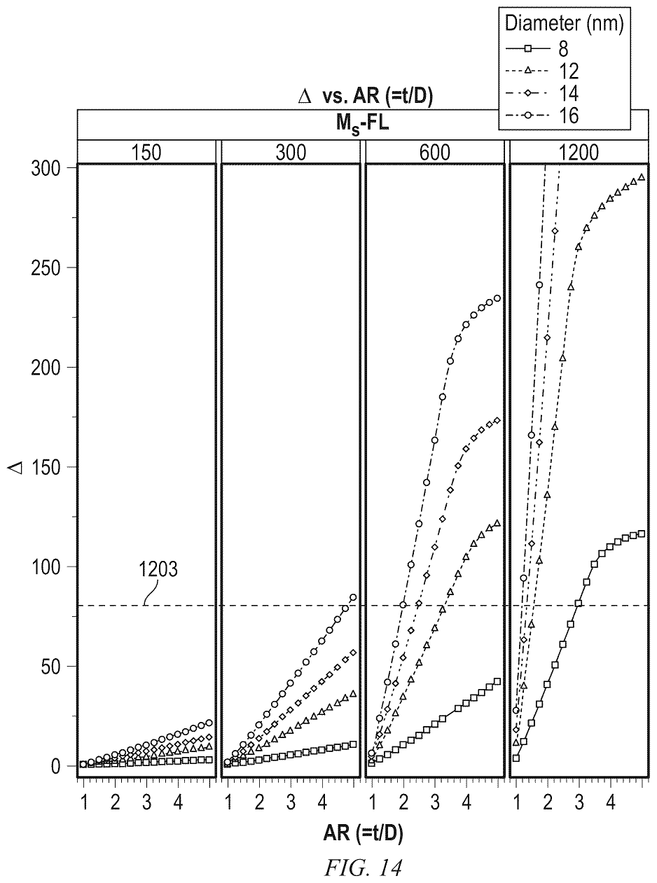

FIGS. 1-8 present a micromagnetic simulation depicting minimum-energy path switching through a quasi-uniform rotation model (critical dimension CD=8 nm). PSA will likely (based on simulations, and experimental data in the iron-boron case) be most applicable to small sizes (<18 nm). The primary switching mechanism is quasi-uniform rotation. The parameter k in FIG. 9 is the “nudge” number. The switching trajectory between two equilibrium states (magnetization pointing up and down) is split into “nudges” or snapshots of the magnetization state, and the calculation method is called Nudged Elastic Band (NEB). The simulation depicted in FIGS. 1-8 was carried out for a relatively long cylinder of magnetic material, i.e., a narrow diameter with large layer thickness which indicates a large aspect ratio, AR, defined as thickness/diameter. In FIG. 1, the magnetic moment points down as indicated by the arrow; the magnetic moment gradually switches to the other direction (up) by FIG. 8. The exemplary simulation took 24 steps. A “large” layer thickness and “large” aspect ratio will be apparent to the skilled artisan, for example, from FIG. 14. See, by way of example and not limitation, Mₛ-FL (free layer magnetization) values of 150, 300, 600 and 1200 emu/cc. A suitable thickness value can be backed out from the diameter and aspect ratio for a value of Δ. Dashed line 1203 represents Δ of 80 and its intersection with the sloped lines provides the value of AR needed for a given diameter MTJ (Note, for low Mₛ-FL, very high AR is needed to reach a Δ of 80). The Δ value of 80 can be chosen, for example, to ensure a desired reliability of an array of devices over a desired lifetime; by way of a non-limiting example, no more than a single device in a large array of devices (e.g., 8 Mbit array) should change state over a ten year period.

FIG. 9 shows a plot of Ek, energy in k_{B}T, versus “nudge” number, k.

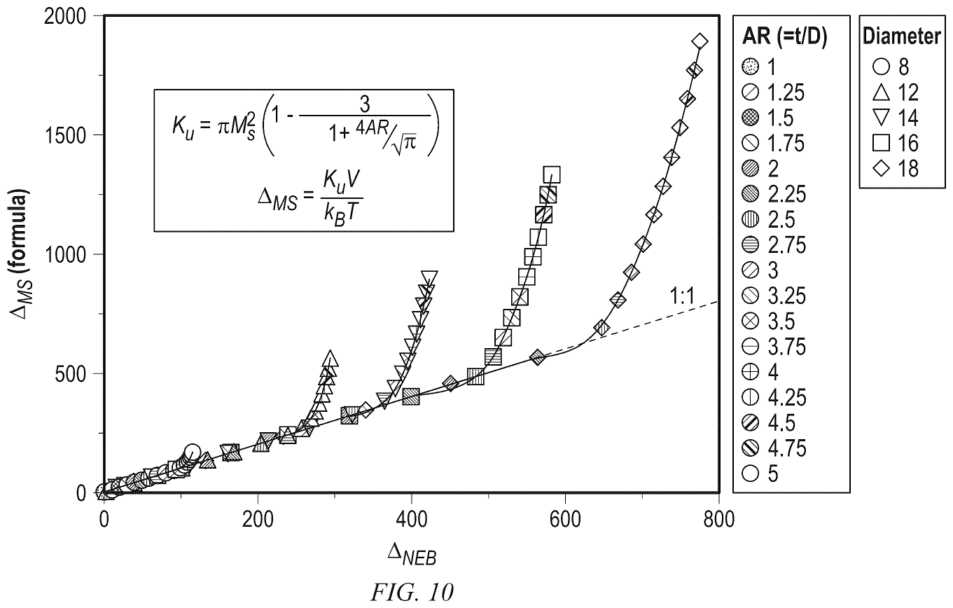

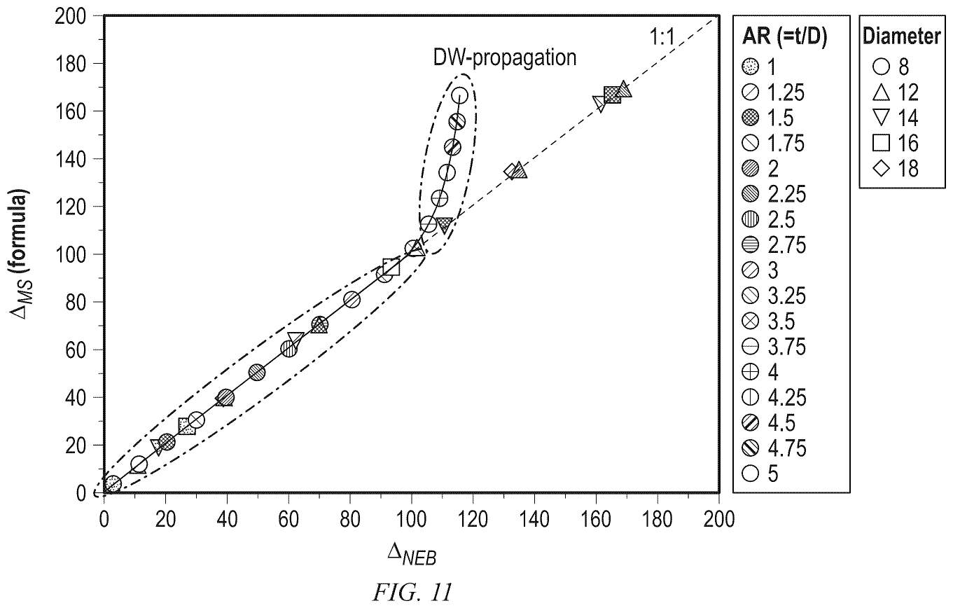

FIGS. 10 and 11 present a comparison of Δ from a macro-spin (MS) based formula and Δ from a micromagnetic simulation (CoFeB, Mₛ=1200 emu/cc). Very good agreement is observed for cases where the aspect ratio (AR) is not too large (when switching becomes non-MS—where the curves diverge from the 1:1 line) and Δ is not increasing as much as expected from macro-spin (MS). In PSA, switching is not domain wall propagation as found in a typical CoFeB layer, but rather is uniform rotation. The macro-spin formula overestimates Δ for AR >3.5. The Δ_{NEB} parameter on the horizontal axis is the thermal stability calculated from using the NEB simulation method. The vertical axis Ams (formula) is an alternative calculation using the macro-spin model. It can be seen that the formula agrees with the simulation for aspect ratios (AR) less than 3.5. AR is determined as thickness (t) divided by diameter (D). It can be concluded, however, that in a certain regime of AR, it is possible to use the macro-spin model formula to obtain Δs.

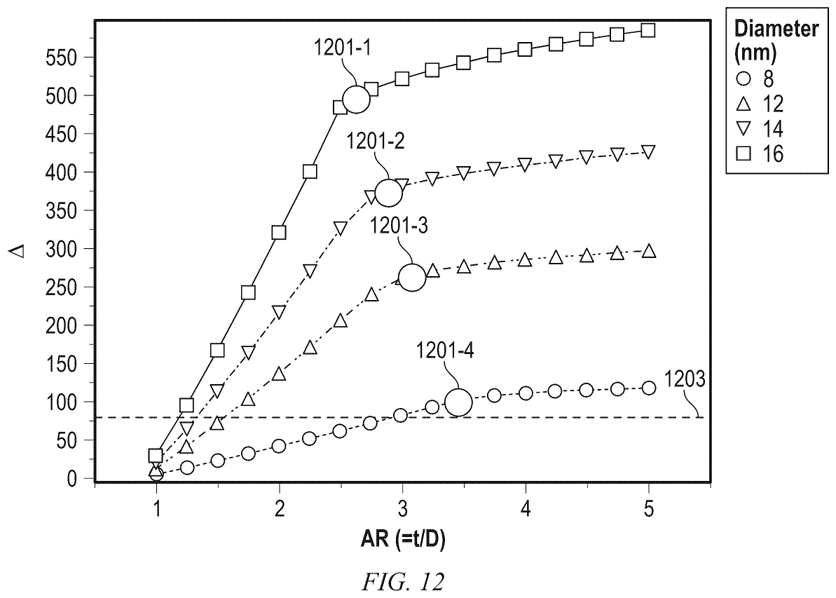

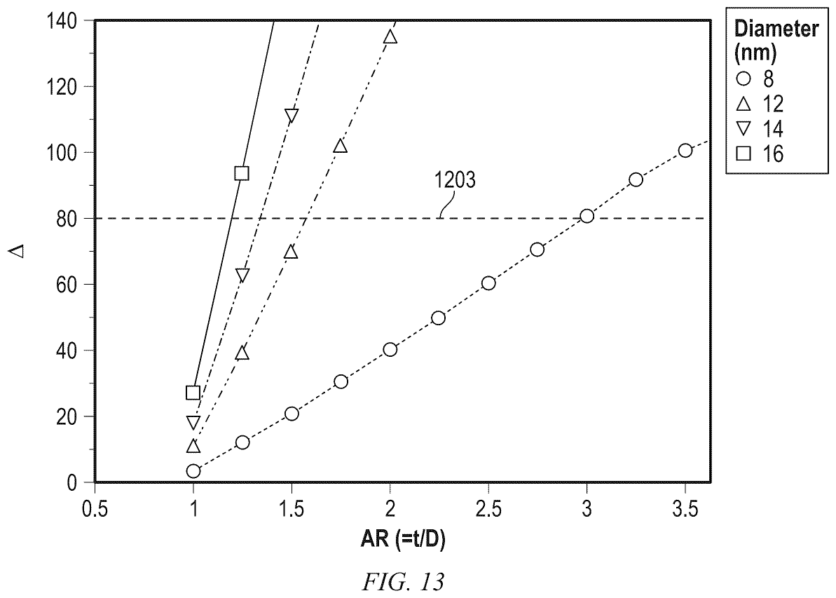

FIGS. 12 and 13 depict effects of diameter and aspect ratio on Δ for the PSA case. FIG. 12 shows the switching by quasi-uniform rotation (or MS-like switching) at low AR; as one goes to a higher AR, there is a transition from MS to DW (domain wall). In the MS case, as seen in FIGS. 1-8, all vectors point in one direction, and they transition from pointing down to pointing up. In the DW model, some part of the pillar has magnetization pointing down, some pointing up, and a domain wall between these two regions. The domain wall moves from one end to the other of the pillar.

It can be seen that the MS to DW transition point 1201-1, 1201-2, 1201-3, 1201-4 moves towards larger AR for smaller diameters. For Δ values of interest (~80 as indicated by the dashed line 1203), the curves are in the MS regime for diameter >8 nm and small AR. Initially, there is a linear increase in Δ with AR; however, at some value, Δ does not increase as much, indicating that the switching mechanism becomes domain wall propagation. From the device perspective, the figure of merit (which is device efficiency) is larger for the macro-spin regime, implying that AR should be below the transition point.

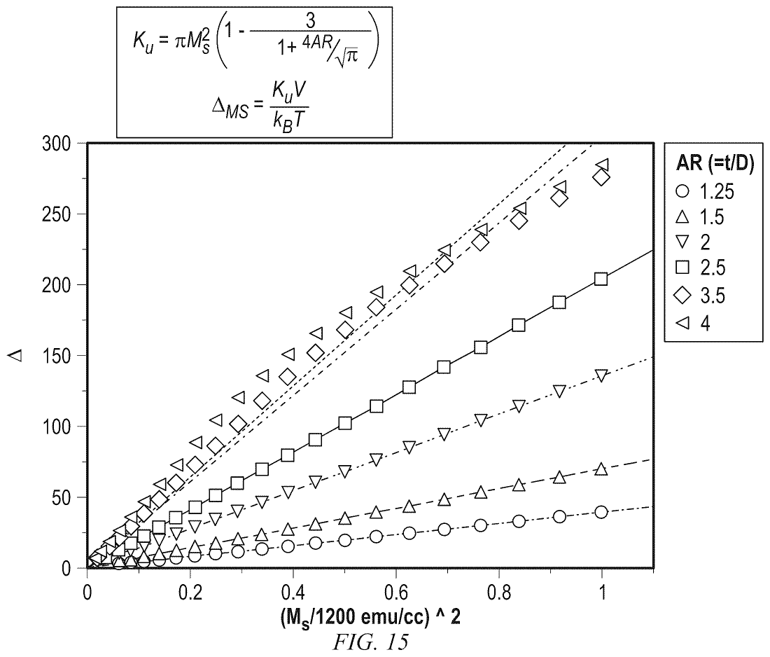

FIGS. 14 and 15 illustrate what happens if different materials with different values of Mₛ are used. From the formula for Kᵤ in FIG. 15 (note that V=volume), Δ is expected to reduce very fast as Mₛ is reduced (because the Mₛ term is squared). NEB modeling confirms Δ·Mₛ² and that Kᵤ can be increased to achieve a larger Δ. FIG. 14 plots Δ against aspect ratio for different diameters and for values of Ms-FL (free layer magnetization) of 150, 300, 600, and 1200 emu/cc. Note that Mn₃Ge has an Ms-FL value of between 150 and 300 emu/cc. It can be seen that thermal stability is poor for lower values of Mₛ. In FIG. 15, the X axis uses a scaled value of Mₛ, where 1200 emu/cc is the scaling factor (based on the saturation magnetization of CoFeB), and is represented as (Mₛ/1200)².

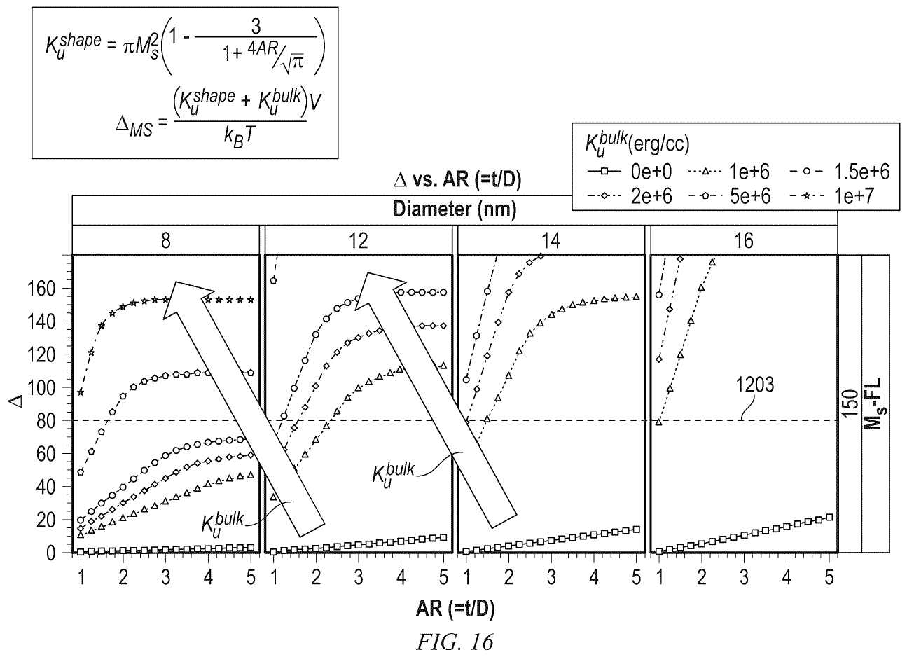

Referring to FIG. 16, consider what can be done to restore Δ for an Mn₃Ge-like free layer. Advantageously, in one or more embodiments, the introduction of bulk anisotropy (which already exists for Mn₃Ge) allows restoration of Δ for MTJs with PSA. Mn₃Ge has a lower Mₛ than CoFeB, which is a conventionally used ferromagnet. As can be seen at the top of FIG. 16, Ams has, in general, two components. For CoFeB, only one component is significant (shape anisotropy, as interfacial anisotropy is negligible and has no bulk anisotropy). For Mn₃Ge, the bulk anisotropy component must also be considered (Mn₃Ge has bulk anisotropy because it is a tetragonal material). When the shape and bulk anisotropy are combined, it is possible increase/restore the Δ for such materials. Good thermal stability can be obtained for Mn₃Ge for certain diameters.

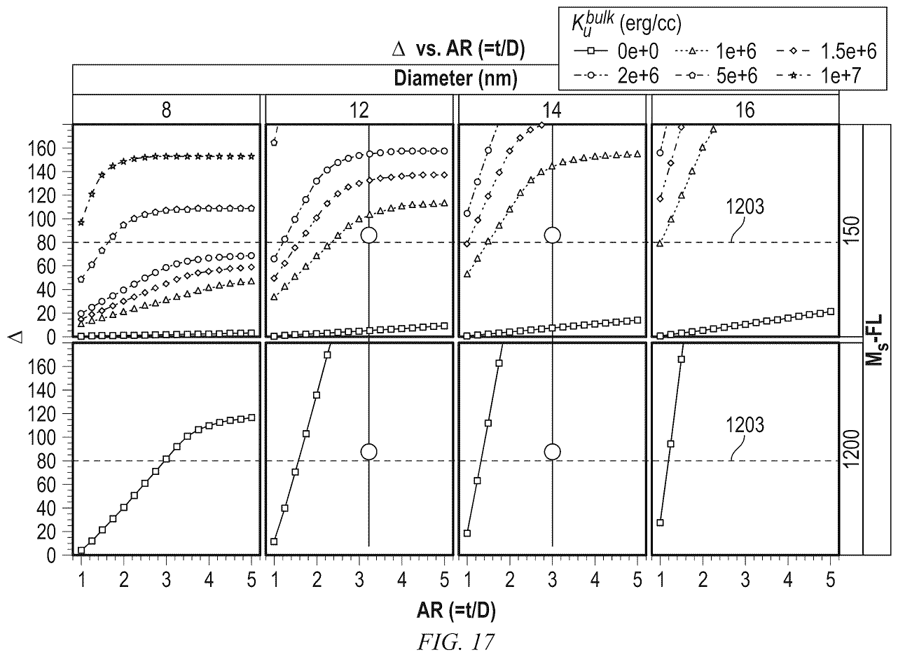

FIG. 17 compares Mn₃Ge to CoFeB. Using quite moderate values of bulk Kᵤ (1.0-1.5×10⁶ erg/cc) for Mn₃Ge, it is possible to match E_{B}=80 k_{B}T and the same AR as for CoFeB. It is expected that low Mₛ and high Kᵤ will lead to improved device performance for faster switching. For Mn₃Ge, the diameter should be <20 nm and the AR should be <2.5. Note that, in a non-limiting example, E_{B}=80 k_{B}T is desirable for arrays of devices while E_{B}=50 k_{B}T is suitable for a single device. Other values can be employed in other embodiments depending on the desired lifetime, size of array, and the like.

FIGS. 18, 19A, and 19B depict embodiments of MTJs with a low Mₛ free layer. In FIG. 18, the free layer 1805 (note double-headed arrow 1821 indicating the switchable magnetization of the free layer) is towards the bottom of the MTJ while the fixed layer 1811 (note single-headed arrow 1823 indicating the magnetization of the fixed layer) is towards the top of the MTJ. Generally, note from bottom to top the substrate 1801, seed layer 1803 (also including a spin-orbit transfer (SOT) line (optional, as discussed further just below) and an overlying templating layer, such as a chemical templating layer (CTL)), low Mₛ magnetic layer 1805, optional polarization enhancement layer 1807, tunnel barrier 1809, magnetic layer 1811, optional synthetic anti-ferromagnetic (SAF) layer 1813, and cap layer 1815. An MTJ device according to aspects of the invention can be used by itself or optionally can be placed on an SOT line and become a three-terminal device. Magnetic layers 1811, 1907 (discussed below) can include, for example, conventional cobalt, iron, nickel, or alloys, or could also include Heusler or half-Heusler materials.

In FIG. 19A, the free layer 1913 (note double-headed arrow 1921 indicating the switchable magnetization of the free layer) is towards the top of the MTJ while the fixed layer 1907 (note single-headed arrow 1923 indicating the magnetization of the fixed layer) is towards the bottom of the MTJ. It is believed that, because the layer 1913 is thick, it can be implemented on top of the tunnel barrier 1909. This belief is based on experimentation, from which it is known that the magnetization of the Heusler compound is thickness dependent and increases quite rapidly with thickness. The critical thickness is material dependent. For the example of Mn₃Ge, a thickness >~20 Å is too thick to be switched by STT. This can be determined for other materials by experimentation, and can possibly at least be bounded, to some extent, based on calculations using the anisotropy energy. Generally, note from bottom to top the substrate 1901, seed layer 1903 with an overlying templating layer, such as a chemical templating layer (CTL), magnetic layer 1907, tunnel barrier 1909, optional polarization enhancement layer 1911, low Mₛ magnetic layer 1913, and cap layer 1915 (also including a spin-orbit transfer (SOT) line). In this aspect, layer 1907 is, for example, a “thick” (discussed further just below) Heusler layer, and layer 1907 will be a fixed/reference layer. In such a case, a SAF (synthetic anti-ferromagnet) layer is not needed, and Heusler magnetic layer 1907 grows on seed layer with CTL 1903 and becomes the reference layer. Furthermore in this regard, one or more embodiments seek to shrink device size. Some current devices range, for example, from 30-35 nm, and do not exhibit shape anisotropy. In contrast, one or more embodiments advantageously employ a low Mₛ material and exhibit shape anisotropy. As noted, in some cases, the free magnetic layer has a diameter less than 20 nm, and in some embodiments as low as 8 nm, for example. Furthermore, some embodiments could have an aspect ratio (AR) of, for example, less than 2.5. When the reference layer 1811, 1907 is a Heusler layer, it can be 33% thicker (optional 40% thicker, optionally 50% thicker) than storage layer 1805, 1913. The reference layer 1811, 1907 will then remain a reference layer and not switch under spin torque switching of the free layer/storage layer. This aspect is pertinent when the reference layer 1811, 1907 is a Heusler layer (e.g., reference layer and storage layer are the same material). When the reference layer is CoFeB coupled to a synthetic anti-ferromagnetic layer, that configuration provides coupling and the specific thickness ratios are not necessarily required.

In FIG. 19B, as in FIG. 19A, the free layer 1913 (note double-headed arrow 1921 indicating the switchable magnetization of the free layer) is towards the top of the MTJ while the fixed layer 1907 (note single-headed arrow 1923 indicating the magnetization of the fixed layer) is towards the bottom of the MTJ. It is believed that, because the layer 1913 is thick, it can be implemented on top of the tunnel barrier 1909. This belief is based on experimentation, from which it is known that the magnetization of the Heusler compound is thickness dependent and increases quite rapidly with thickness. The critical thickness is material dependent. For the example of Mn₃Ge, a thickness >~20 Å is too thick to be switched by STT. This can be determined for other materials by experimentation, and can possibly at least be bounded, to some extent, based on calculations using the anisotropy energy. Generally, note from bottom to top the substrate 1901, seed layer 1903A, synthetic anti-ferromagnetic layer 1905, magnetic layer 1907, tunnel barrier 1909, optional polarization enhancement layer 1911, low Mₛ magnetic layer 1913, and cap layer 1915 (also including a spin-orbit transfer (SOT) line). In this aspect, layer 1907 is, for example, a conventional material (e.g., CoFeB) such as is used in current MRAM. In this aspect, seed layer 1903A need not include a CTL, the SAF layer 1905 on seed layer 1903A is coupled to magnetic layer 1907 such as CoFeB and this becomes reference layer.

In one aspect, an exemplary structure includes a substrate 1801. As seen at 1803, also included are a seed layer overlying the substrate and a templating layer including a binary alloy having a CsCl structure overlying the seed layer. An ordered magnetic alloy having magneto-crystalline anisotropy overlies the templating layer as seen at 1805. In one or more embodiments, the ordered magnetic alloy has a diameter <20 nm, and furthermore, the ordered magnetic layer has magnetization substantially perpendicular to the layer.

In some cases, the ordered alloy is a Heusler compound such as Mn₃Ge. In one or more embodiments, this Heusler layer has a thickness/diameter ratio of less than 2.5.

In one or more embodiments, the chemical templating layer (CTL), which is the binary alloy with CsCl structure, is represented by A₁₋ₓEₓ, where A is a transition metal element and E is a main group element. For example, A includes Co and E includes at least aluminum or gallium and possibly traces of other elements (e.g., Al or Ga; or Al alloyed with Ga, Ge, Sn, or any combination thereof, such as AlSn, AlGe, AlGaGe, AlGaSn, AlGeSn, and AlGaGeSn), and x is in the range from 0.42 to 0.55.

In some cases, the ordered alloy is a C38 compound such as AlMnGe.

Generally, in one or more embodiments, the ordered alloy, whether a Heusler alloy such as Mn₃Ge or other Heusler alloy, a C38 compound, or the like has a thickness/diameter ratio of less than 2.5

A non-limiting example of a suitable tunnel barrier is MgO.

Other examples of suitable Heusler compounds include Mn₃Sn, Mn₃Sb, Mn₂CoSn, Mn₂FeSb, Mn₃CoAl, Mn₂CoGe, Mn₂CoSi, Mn₂CuSi, Co₂CrAl, Co₂CrSi, Co₂MnSb, and Co₂MnSi. Here as well, the Heusler layer can, for example, have a thickness/diameter ratio of less than 2.5.

In some cases, MgAl₂O₄ can be used as a tunnel barrier whose lattice spacing can be tuned (engineered) by controlling the Mg—Al composition to result in better lattice matching with the Heusler compounds (e.g., the composition of this tunnel barrier can be represented as Mg_{1-z}Al_{2+(2/3)z}O₄, wherein −0.5<z<0.5).

In some embodiments, CD (such as diameter) is less than 20 nm, and the device has a circular cross section? A circular cross section is helpful in one or more embodiments because in the case of some other shape such as a trapezoid or diamond, the magnetization in the corners will create a pinning site where it is hard to switch orientations. Also, with currently known etching processes such as ion milling, it is easier to make circular cross sections. For example, write a feature which is bigger and just keep rotating the sample and milling from the side so the size of the junction shrinks.

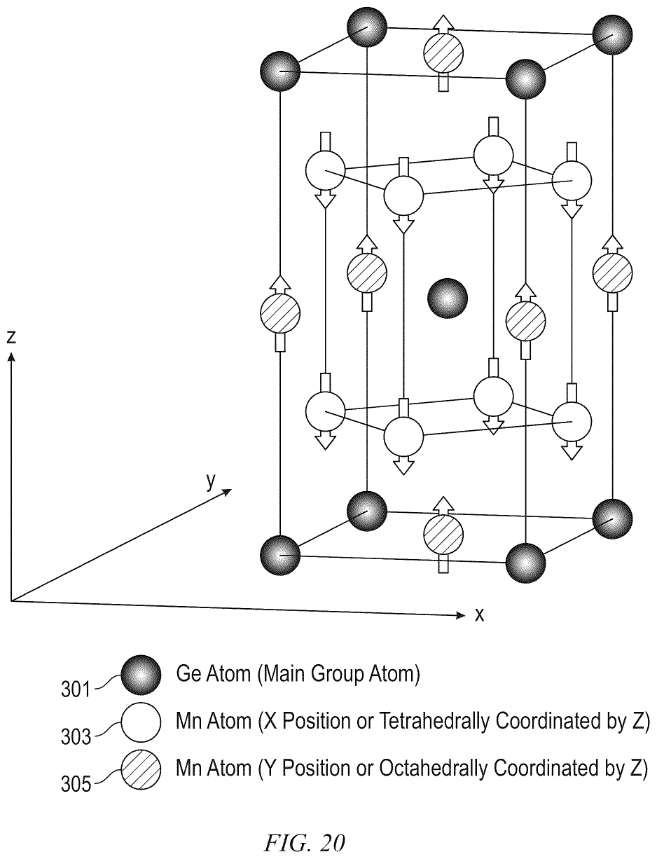

One or more embodiments make use of a templating layer (in a non-limiting example, a chemical templating layer (CTL)). Referring to FIG. 20 consider now aspects of an exemplary chemical templating layer. A Heusler compound such as Mn₃Ge (alternately Mn₃Sn or Mn₃Sb) includes alternating layers of Mn—Mn and Mn—Ge atoms. In FIG. 20, atoms with shading 301 represent Ge atoms (main group), atoms with shading 303 represent Mn atoms of the X-position in X₂YZ (tetrahedrally coordinated by Z), and atoms with shading 305 represent element Mn atoms of the Y-position in X₂YZ (octahedrally coordinated by Z). Mn is a transition metal and Ge is from the main group of the periodic table. One of the alternating layers contains transition metal atoms 303 only and other contains main group element atoms 301 along with transition metal atoms 305. Thus, a seed layer containing a single element which lattice-matches the in-plane lattice constant does not promote growth of an ordered Heusler compound at low temperatures such as room temperature. An ideal seed layer includes a binary compound of a transition element and a main group element. Moreover, this ideal seed layer also has an alternating layer structure containing these two distinct elements. One layer has only the transition metal. The other layer has only the main group element (the “Z” in X₂YZ is a main group element as well). These binary compounds have a CsCl-like (cesium chloride-like) structure (where each cesium ion is coordinated by eight chloride ions). Exemplary templating layers include CoAl, CoGa, others as discussed elsewhere herein, and the like.

Referring to the crystal structure in FIG. 20, all 3 axes are not the same; dimensions a and b (not labelled in the figure, along the x and y axes) are the same in the depicted example, while dimension c (not labelled in the figure, along the vertical z axis) is different. Note the magnetization arrows going up and down along z. Stretching of crystals in the z direction yields volume anisotropy. Note the alternating layer structure. Use of a seed layer with alternating layer structure containing two distinct elements (one transition metal and other main group element) allows for chemical ordering even during room-temperature growth.

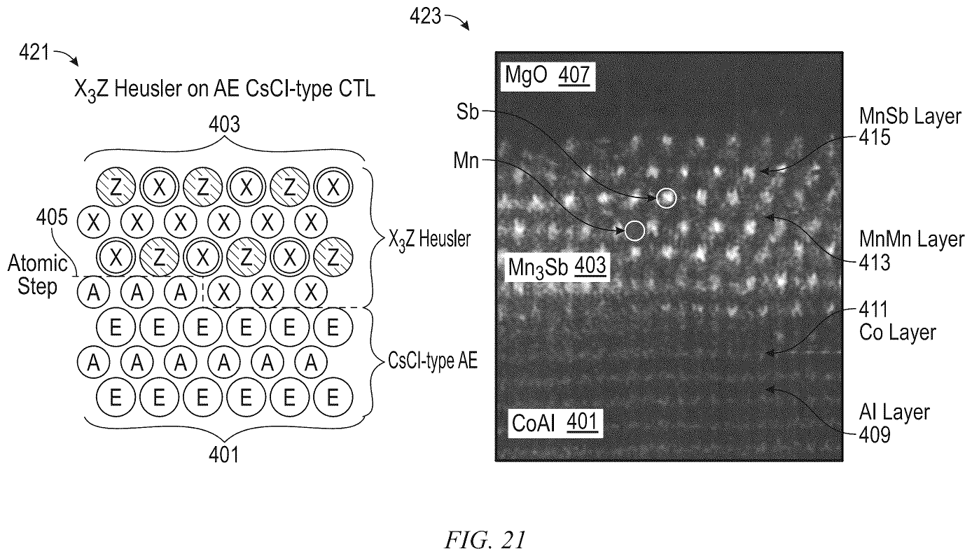

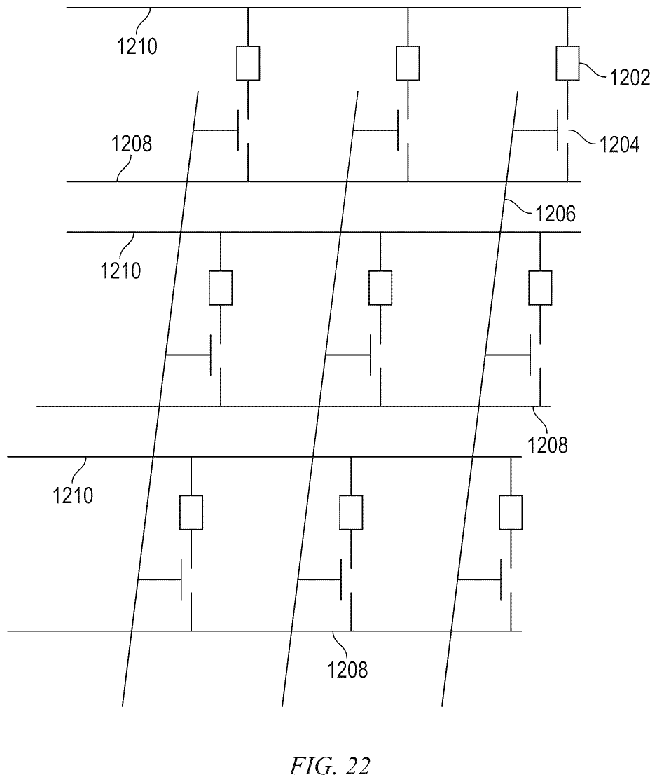

Referring now to FIG. 21, one or more embodiments employ a CsCl-type chemical templating layer (CTL) 401 (CoAl is an example of an excellent CsCl-type CTL) which promotes growth of an ordered Heusler compound even at ultrathin thicknesses and at room temperature. “E” can correspond, for example, to Al and “A” can correspond, for example, to Co. In FIG. 21, view 421 is a schematic while view 423 is a transmission electron microscopy (TEM) image. A Heusler compound such as Mn₃Ge or Mn₃Sn or Mn₃Sb 403 grows epitaxially on top of the CoAl layer 401. In one or more embodiments, the in-plane lattice constant of the ultrathin (<~25 Å) Heusler compound is similar to that of the CoAl CTL layer. It is possible to strain the Heusler layer to a differing extent with appropriate choice of the CTL layer. We have found that even ternary Heusler compounds can be ordered by the CTL. Note that one or more embodiments use alternative templating layers so that the lattice constant of the Heusler layer more closely matches that of the alternative oxide tunnel barrier.

In the example of FIG. 21, the in-plane lattice constant of the ultrathin Heusler compound is similar to that of the CoAl CTL. It is possible to strain the Heusler to a differing extent with an appropriate choice of CTL. We have found that even ternary Heusler compounds can be ordered by the CTL. As illustrated, the Mn (generally, X) grows on the Al and the Sb (generally, Z) grows on the Co. Note the atomic step 405. The Heusler material can be strained and thus adopts the in-plane lattice constant of the template material. One or more embodiments impose the lattice constant of the templating layer onto the Heusler layer. In view 423, note that CoAl 401 includes Al layers 409 and Co layers 411 and the Mn₃Sb 403 includes MnMn layer 413 and MnSb layer 415. Note the MgO tunnel barrier 407. The three most prominent tetragonal compounds are Mn₃Ge, Mn₃Sn, and Mn₃Sb, and Mn₃Sb has a larger difference in atomic number between Mn and Sb and thus is easier to see in the TEM image 423.

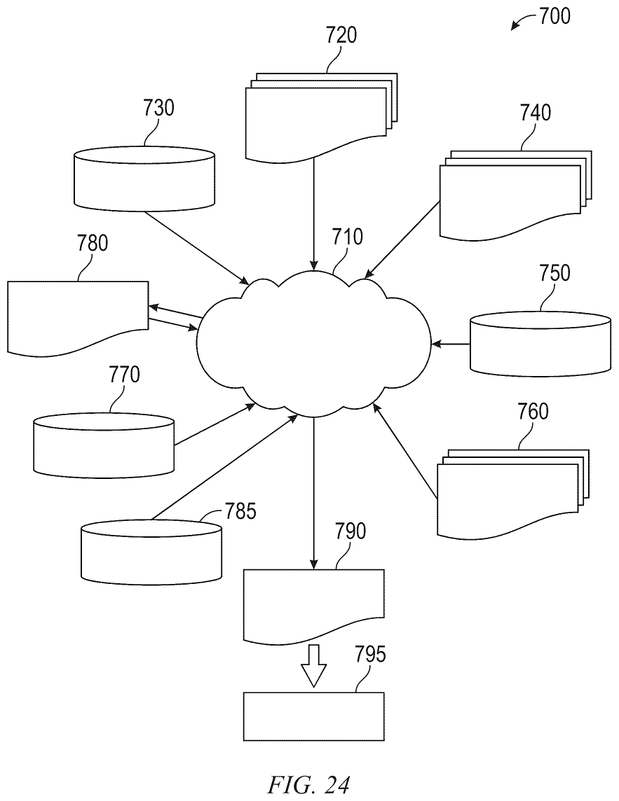

In FIGS. 18, 19A, and 19B, the substrate can be silicon with CMOS circuitry such as transistors and access lines permitting selection of individual devices. Other than the novel cells described herein, conventional transistors, access lines, peripheral circuits, and the like can be employed—refer to discussion of FIGS. 22 and 24 below. Heusler layers can be formed, for example, by epitaxial growth on the CTL. The polarization enhancement layer can be, for example, a thin layer of magnetic material such as cobalt. The Synthetic Anti-Ferromagnet (SAF) layer can include, for example, a Co/Pt multilayer that is magnetically coupled to the corresponding magnetic layer to achieve needed performance. A thin layer (not shown) of Ta or Ir or Ru (order of few Å) may typically be interposed between the magnetic layer and the SAF layer. The cap layer may include, purely by way of example and not limitation, Mo, W, Ta, Pt, Ru, or a combination thereof.

By way of review, the Heusler layer can be produced via growth on a suitable templating layer. In a templating concept a templating layer is grown and another layer (e.g., Heusler compound) is grown on top of it. Templating essentially means that the layer being grown on the templating layer grows to the lattice constant a of the underlayer/seed layer.

As will be appreciated by the skilled artisan, typically, the magnetization is not fixed, but rather, the magnetization precesses like a spinning top at a non-zero temperature. This can change depending on temperature. In view of this precession, perpendicularity, as used herein, refers to perpendicularity of the time integral/average of the path of the magnetization. The time integral/average of the path of the magnetization could be, for example, “exactly” perpendicular, perpendicular within ±5%, or perpendicular within ±10%.

It should be noted that the Heusler compounds are indicated by stoichiometric formulas and this does not preclude small variations of up to several % from the nominal values.

Referring now to FIG. 22, an array of MRAM devices 1202 is shown. Each cell 1202 (e.g., embodiment of FIG. 18, 19A, or 19B) is connected to a respective transistor 1204 that controls reading and writing. A word line 1206 provides data to write to the cells 1202, while a bit line 1210 and a bit line complement 1208 read data from the cell 1202. In this manner, a large array of memory devices can be implemented on a single chip. An arbitrarily large number of cells 1202 can be employed, within the limits of the manufacturing processes and design specifications.

Writing data to a cell 1202 includes passing a current through the cell. This current causes the direction of magnetization to switch between a parallel or anti-parallel state, which has the effect of switching between low resistance and high resistance. Because this effect can be used to represent the 1s and 0s of digital information, the cells 1202 can be used as a non-volatile memory. Passing the current in one direction through the cell 1202 causes the magnetization of the free layer to be parallel with that of the reference layer, while passing the current in the other direction through the cell 1202 causes the magnetization of the free layer to be antiparallel to that of the reference layer. Reading the bit stored in a cell 1202 involves applying a voltage (lower than that used for writing information) to the cell 1202 to discover whether the cell offers high resistance to current (“1”) or low resistance (“0”).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, ion milling, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method produces novel structures, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008. It is emphasized that while some individual processing steps are set forth herein, those steps are merely illustrative, and one skilled in the art may be familiar with several equally suitable alternatives that would be applicable. For example, given the teachings herein, the skilled artisan can fabricate one or more embodiments by adapting known techniques, for example, scaled down to a dimension (e.g., diameter) less than, for example, 35 nm, or less than, for example, 20 nm, or even less than, for example, 15 nm.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

In another aspect, referring to FIG. 22, a magnetoresistive random-access memory array includes a plurality of bit lines 1210 and a plurality of complementary bit lines 1208 forming a plurality of bit line-complementary bit line pairs. A plurality of word lines 1206 intersect the plurality of bit line pairs at a plurality of cell locations. A plurality of magnetoresistive random-access memory cells 1202 are located at each of the plurality of cell locations. Each of the magnetoresistive random-access memory cells 1202 is electrically connected to a corresponding bit line 1210 and selectively interconnected to a corresponding one of the complementary bit lines 1208 under control of a corresponding one of the word lines 1206 (e.g., a respective transistor 1204 is a field effect transistor turned off or on by a signal from word line 1206 applied to its gate, which controls reading and writing and whether the cell is coupled to the complementary bit lines).

Each of the plurality of magnetoresistive random-access memory cells includes a cell as described elsewhere herein with respect to FIG. 18, 19A, or 19B. The cells are connected between the bit lines 1210 and the access FETs 1204. Typically, the capping (“cap”) layer of the devices indicated in FIG. 18, 19A, or 19B connect to the bit line 1210.

In still another aspect, an exemplary method of operation includes providing an array such as just described, applying signals to the word lines 1206 to cause a first subset of the cells 1202 to store logical ones and a second subset of the cells 1202 to store logical zeroes; and reading the stored logical ones and zeroes via the bit lines 1210 and the complementary bit lines 1208.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from magnetic tunnel junctions having a free layer with low magnetization and perpendicular shape anisotropy and the like.

An integrated circuit in accordance with aspects of the present inventions can be employed in essentially any application and/or electronic system where magnetic tunnel junctions having a free layer with low magnetization and perpendicular shape anisotropy and the like would be beneficial. Given the teachings of the present disclosure provided herein, one of ordinary skill in the art will be able to contemplate other implementations and applications of embodiments disclosed herein.

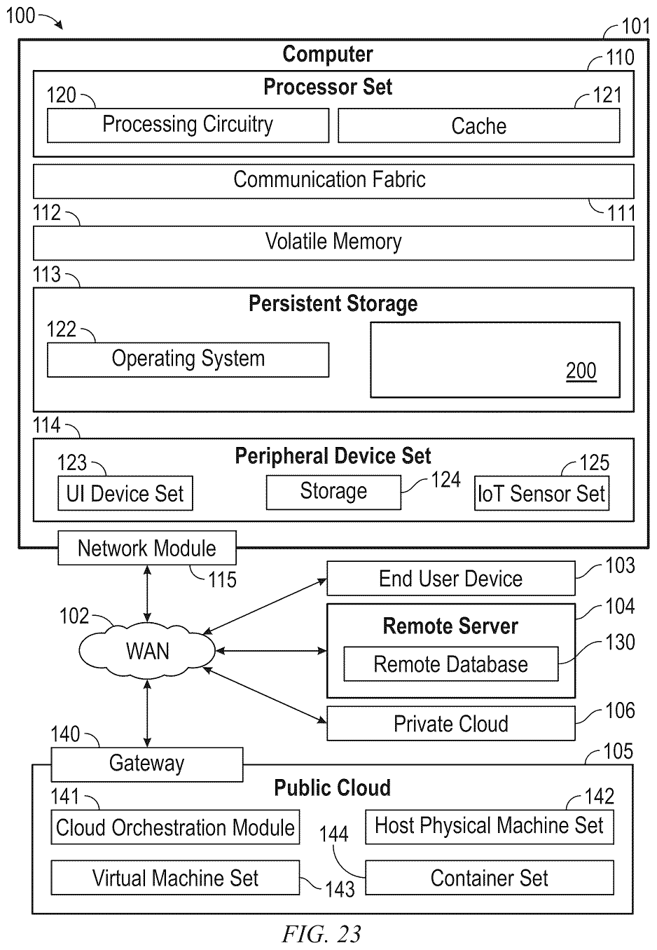

Reference should now be had to FIG. 23, which depicts a computing environment according to an embodiment of the present invention (e.g., for implementing a design process such as that of FIG. 24).

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as a system 200 for semiconductor design and/or control of semiconductor fabrication (see FIG. 24). In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 23. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer, and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Exemplary Design Process Used in Semiconductor Design, Manufacture, and/or Test

One or more embodiments make use of computer-aided semiconductor integrated circuit design simulation, test, layout, and/or manufacture. In this regard, FIG. 24 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those that can be analyzed using techniques disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 24 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like. In one embodiment, design structure 790 may comprise a compiled, executable HDL simulation model that functionally simulates the devices to be analyzed.

Design structure 790 may also employ a data format used for the exchange of layout data of integrated circuits and/or symbolic data format (e.g. information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein (e.g., .lib files). Design structure 790 may then proceed to a stage 795 where, for example, design structure 790: proceeds to tape-out, is released to manufacturing, is released to a mask house, is sent to another design house, is sent back to the customer, etc.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A magnetoresistive random-access memory cell, comprising:
a fixed magnetic layer;
a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and
a tunnel barrier between the fixed and free magnetic layers.

2. The magnetoresistive random-access memory cell of claim 1, further comprising:
a substrate;
a cap layer;
a seed layer overlying the substrate; and
a templating layer overlying the seed layer, the templating layer including a binary alloy having a CsCl structure;
wherein the free magnetic layer overlies the templating layer, the tunnel barrier is outward of the free magnetic layer, the fixed magnetic layer is outward of the tunnel barrier, and the cap layer is outward of the fixed magnetic layer.

3. The magnetoresistive random-access memory cell of claim 2, wherein the ordered magnetic alloy comprises a Heusler compound.

4. The magnetoresistive random-access memory cell of claim 3, wherein the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

5. The magnetoresistive random-access memory cell of claim 4, wherein the Heusler compound is Mn₃Ge.

6. The magnetoresistive random-access memory cell of claim 5, wherein the binary alloy with CsCl structure is represented by A₁₋ₓEₓ, where A is a transition metal element and E is a main group element including at least one of aluminum or gallium, and x is in a range from 0.42 to 0.55.

7. The magnetoresistive random-access memory cell of claim 2, wherein the free magnetic layer has a thickness/diameter ratio of less than 2.5.

8. The magnetoresistive random-access memory cell of claim 2, wherein the ordered magnetic alloy comprises a C38 compound.

9. The magnetoresistive random-access memory cell of claim 1, further comprising:
a substrate;
a cap layer; and
a seed layer overlying the substrate;
wherein the fixed magnetic layer is outward of the seed layer, the tunnel barrier is outward of the fixed magnetic layer, the free magnetic layer is outward of the tunnel barrier, and the cap layer is outward of the free magnetic layer.

10. The magnetoresistive random-access memory cell of claim 9, wherein:
the seed layer includes an overlying templating layer; and
the fixed magnetic layer comprises a Heusler layer.

11. The magnetoresistive random-access memory cell of claim 10, wherein the Heusler layer has a thickness at least 33 percent greater than that of the free magnetic layer.

12. The magnetoresistive random-access memory cell of claim 10, wherein the ordered magnetic alloy comprises a Heusler compound.

13. The magnetoresistive random-access memory cell of claim 12, wherein the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

14. The magnetoresistive random-access memory cell of claim 13, wherein the Heusler compound is Mn₃Ge.

15. The magnetoresistive random-access memory cell of claim 10, wherein the free magnetic layer has a thickness/diameter ratio of less than 2.5.

16. The magnetoresistive random-access memory cell of claim 10, wherein the ordered magnetic alloy comprises a C38 compound.

17. The magnetoresistive random-access memory cell of claim 9, wherein:
the fixed magnetic layer comprises CoFeB.

18. The magnetoresistive random-access memory cell of claim 17, wherein the ordered magnetic alloy comprises a Heusler compound.

19. The magnetoresistive random-access memory cell of claim 18, wherein the Heusler compound is selected from the group consisting of Mn₃Ge, Mn₃Sn, Mn₃Sb, Mn₂CoSn, Mn₂FeSb, Mn₂CoAl, Mn₂CoGe, Mn₂CoSi, Mn₂CuSi, Co₂CrAl, Co₂CrSi, Co₂MnSb, and Co₂MnSi.

20. The magnetoresistive random-access memory cell of claim 19, wherein the Heusler compound is Mn₃Ge.

21. The magnetoresistive random-access memory cell of claim 17, wherein the free magnetic layer has a thickness/diameter ratio of less than 2.5.

22. The magnetoresistive random-access memory cell of claim 17, wherein the ordered magnetic alloy comprises a C38 compound.

23. A magnetoresistive random-access memory array, comprising:
a plurality of bit lines and a plurality of complementary bit lines forming a plurality of bit line-complementary bit line pairs;
a plurality of word lines intersecting the plurality of bit line pairs at a plurality of cell locations; and
a plurality of magnetoresistive random-access memory cells located at each of the plurality of cell locations, each of the magnetoresistive random-access memory cells being electrically connected to a corresponding bit line and selectively interconnected to a corresponding one of the complementary bit lines under control of a corresponding one of the word lines, each of the plurality of magnetoresistive random-access memory cells comprising:
a fixed magnetic layer;
a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and
a tunnel barrier between the fixed and free magnetic layers.

24. A hardware description language (HDL) design structure encoded on a machine-readable data storage medium, the HDL design structure comprising elements that when processed in a computer-aided design system generates a machine-executable representation of a magnetoresistive random-access memory cell, wherein the magnetoresistive random-access memory cell comprises:
a fixed magnetic layer;
a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and
a tunnel barrier between the fixed and free magnetic layers.

25. A hardware description language (HDL) design structure encoded on a machine-readable data storage medium, the HDL design structure comprising elements that when processed in a computer-aided design system generates a machine-executable representation of a magnetoresistive random-access memory array, wherein the magnetoresistive random-access memory array comprises:
a plurality of bit lines and a plurality of complementary bit lines forming a plurality of bit line-complementary bit line pairs;
a plurality of word lines intersecting the plurality of bit line pairs at a plurality of cell locations; and
a plurality of magnetoresistive random-access memory cells located at each of the plurality of cell locations, each of the magnetoresistive random-access memory cells being electrically connected to a corresponding bit line and selectively interconnected to a corresponding one of the complementary bit lines under control of a corresponding one of the word lines, each of the plurality of magnetoresistive random-access memory cells comprising:
a fixed magnetic layer;
a free magnetic layer formed from an ordered magnetic alloy, the free magnetic layer having a diameter less than 20 nm, the free magnetic layer exhibiting magneto-crystalline anisotropy with magnetization substantially perpendicular to the free magnetic layer; and
a tunnel barrier between the fixed and free magnetic layers.
